(19) United States
(12) Patent Application Publication
(10) Pub. No.: US 2013/0170167 A1
(43) Pub. Date: Jul. 4, 2013

(54) PRINTED CIRCUIT BOARD

(71) Applicants: Toyohide Miyazaki, Tsukuba-shi (JP); Kenji Koyama, Tsu-shi (JP)

(72) Inventors: Toyohide Miyazaki, Tsukuba-shi (JP); Kenji Koyama, Tsu-shi (JP)

(73) Assignee: CANON KABUSHIKI KAISHA, Tokyo (JP)

(21) Appl. No.: 13/821,800

(22) PCT Filed: Sep. 16, 2011
(86) PCT No.: PCT/JP2011/005246

§ 371 Date: Mar. 8, 2013

(30) Foreign Application Priority Data
Sep. 24, 2010 (JP) 2010-214397

(51) Int. Cl. H05K 1/02

(52) U.S. Cl. CPC H05K 1/0216
USPC 361/783

(57) ABSTRACT

A multi-layer printed circuit board includes an embedded capacitor substrate composed of a power source conductor layer and a ground conductor layer, the layers being disposed close to each other. The power source conductor layer has a first power source plane to supply power to a circuit element, and a second power source plane that is separated from the first power source plane by a gap and functions as a main power source. The first power source plane is partially connected to the second power source plane by a connecting line. The ground conductor layer has an opening at a position overlapping with a projected image when the connecting line is projected on the ground conductor layer. This structure suppresses propagation of the noise caused at the circuit element and reduces radiation noise in the printed circuit board.

### TECHNICAL FIELD

The present invention relates to a printed circuit board having a circuit element thereon.

### BACKGROUND ART

Printed circuit boards with a circuit element mounted thereon such as integrated circuit (IC) and large-scale integration (LSI) are known to have a problem: the circuit element in a printed circuit board causes electromagnetic wave noise when turned on/off, and the noise adversely affects the other circuits of the electronic device that incorporates the printed circuit board and the other electronic devices, leading to malfunction. The noise is caused mainly by the parasitic capacitance component and the inductance component of the wiring structure electrically connecting circuit elements, and by the high-frequency current flowing through the electromagnetic coupling of these components.

In recent years, ICs and LSIs have extensively increased in processing speed to have operating frequencies from hundreds of MHz to several GHz. In the operating frequency range exceeding hundreds of MHz, the parasitic components of a noise suppression element itself or the wiring structure in the printed circuit board more and more adversely affect the circuits, so that the noise suppression components cannot achieve their original function, providing only insufficient suppression effect.

U.S. Pat. No. 5,079,069 discusses use of an embedded capacitor substrate to suppress radiation noise at a frequency band exceeding hundreds of MHz. In the embedded capacitor substrate, a printed circuit board is configured to have a structure of a capacitor having a small parasitic inductance component. The embedded capacitor substrate includes a power source conductor layer and a ground conductor layer, and uses these entire layers as electrodes, and further has a thin dielectric layer with a thickness of 100 micrometer or less disposed between the power source conductor layer and the ground conductor layer to form a capacitor.

However, in the embedded capacitor substrate using the entire power source conductor layer and ground conductor layer as electrodes, noise caused locally by operation of circuit element is propagated over the substrate, increasing radiation noise.

### CITATION LIST

### Patent Literature

PTL 1: U.S. Pat. No. 5,079,069

### SUMMARY OF INVENTION

The present invention provides a printed circuit board having a circuit element thereon, in which radiation noise is reduced by suppressing propagation of noise caused by a circuit element.

The present invention provides a printed circuit board including a power source conductor layer, a ground conductor layer, and a signal wiring layer having a circuit element thereon, the power source conductor layer, the ground conductor layer, and the signal wiring layer being multilayered with a dielectric layer interposed therebetween. The printed circuit board further includes a first power source plane provided in the power source conductor layer, a second power source plane provided in the power source conductor layer at a position separated from the first power source plane by a gap, a connecting line connecting the first power source plane to the second power source plane, and a ground plane provided in the ground conductor layer, wherein the ground plane has an opening at a portion overlapping with the image of the connecting line when projected onto the ground conductor layer.

Further features of the present invention will become apparent from the following description of exemplary embodiments with reference to the attached drawings.

### BRIEF DESCRIPTION OF DRAWINGS

The accompanying drawings, which are incorporated in and constitute a part of the specification, illustrate exemplary embodiments, features, and aspects of the invention and, together with the description, serve to explain the principles of the invention.

FIG. 1 schematically illustrates a printed circuit board according to an exemplary embodiment.

FIG. 2 is a circuit diagram illustrating a printed circuit board according to an exemplary embodiment.

FIG. 3 is an exploded perspective diagram of a simulation model of a printed circuit board according to an exemplary embodiment.

FIG. 4 is an exploded perspective diagram of a simulation model of a printed circuit board in a comparative example.

FIG. 5 is a graph illustrating simulation results of the printed circuit boards according to an exemplary embodiment and a comparative example respectively.

FIG. 6A is a plan view illustrating a ground conductor layer of a printed circuit board according to an exemplary embodiment.

FIG. 6B is a plan view illustrating a power source conductor layer of a printed circuit board according to an exemplary embodiment.

FIG. 7A is a graph illustrating the effect of suppressing noise propagation in a simulation model of a printed circuit board according to an exemplary embodiment.

FIG. 7B is a graph illustrating the effect of suppressing noise propagation in a simulation model of a printed circuit board according to an exemplary embodiment.

### DESCRIPTION OF EMBODIMENTS

Various exemplary embodiments, features, and aspects of the invention will be described in detail below with reference to the drawings.

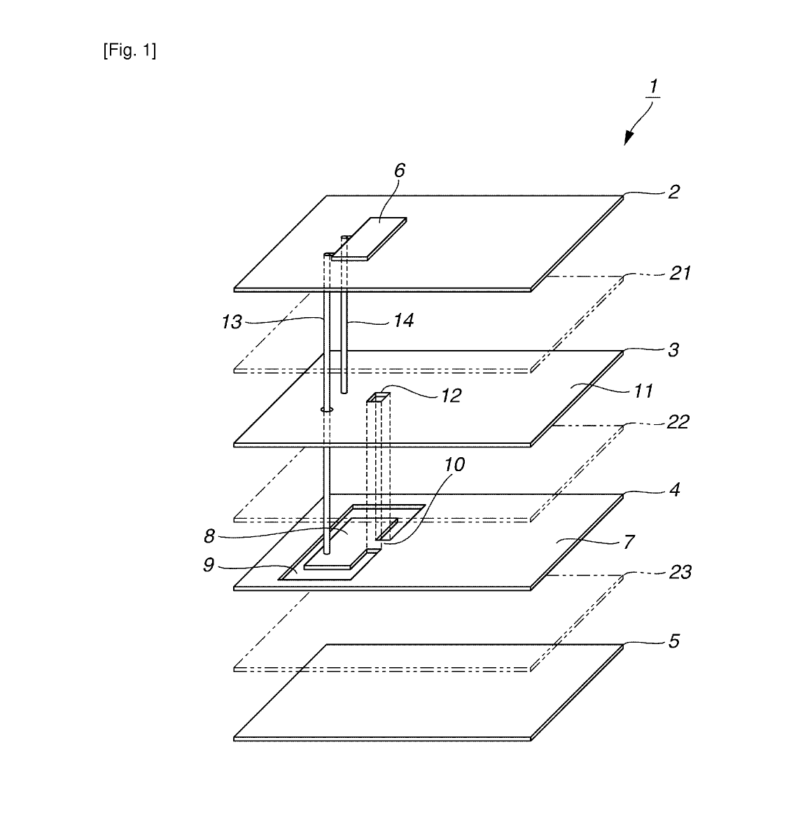

FIG. 1 schematically illustrates a printed circuit board according to an exemplary embodiment. A printed circuit board 1 according to the present exemplary embodiment is a multi-layer printed circuit board having a first signal wiring layer 2, a ground conductor layer 3, a power source conductor layer 4, and a second signal wiring layer 5, the layers being multilayered in sequence with insulator layers (conductor layers) 21, 22, and 23 respectively interposed therebetween.

The insulator layers 21, 22, and 23 are provided with an isolator (dielectric) that is composed of resin or glass fiber for example. The power source conductor layer 4 is located opposite the ground conductor layer 3 with the insulator layer 22 interposed therebetween to form an embedded capacitor. The insulator layer 22 in the embedded capacitor satisfies the following condition either (1) or (2), or both of (1) and (2): (1) having a thickness of 100 micrometer or less; and (2) being composed of a high dielectric material having a relative permittivity of 5 or more. The first wiring layer 2 has a semiconductor apparatus 6 as a circuit element such as IC and LSI provided with signal lines, power source lines, and ground lines (not illustrated). Furthermore, while the first signal wiring layer 2 and the second signal wiring layer 5 are signal wiring layers mainly for supplying a signal to the semiconductor apparatus 6, other than wiring layers for signals, a conductor for ground and a conductor for the power source can also be provided there.

The power source conductor layer 4 includes a main power supply plane 7 and an IC power supply plane 8 separated from each other by a gap. The main power supply plane 7 is connected to the IC power supply plane 8 by a connecting line 10.

The IC power supply plane 8 is a first power source plane to supply a power source potential (power) supplied from the main power supply plane 7 to the semiconductor apparatus 6. The IC power supply plane (first power source plane) 8 preferably has a size to accommodate the area of an image of the semiconductor apparatus 6 when projected onto the power source conductor layer 4. In the present exemplary embodiment, the IC power supply plane 8 has a size to fit (the same size as that of) an image of the semiconductor apparatus 6 when projected onto the power source conductor layer 4. The semiconductor apparatus 6 has a power source terminal connected to the IC power supply plane 8 through a via 13.

The main power supply plane 7 is a second power source plane provided in the power source conductor layer 4, and separated from the IC power supply plane 8 by a gap. More specifically, the main power supply plane 7 has an approximately C-shaped opening 9 which separates the IC power supply plane 8 as an island from the main power supply plane 7. The connecting line 10 connects the IC power supply plane 8 to the main power supply plane 7.

The connecting line 10 is a linear strip connecting a side of the main power supply plane 7 to a side of the IC power supply plane 8 which are opposing each other. In the above structure, power can be supplied to the power source terminal of the semiconductor apparatus 6. In FIG. 1, only one connecting line 10 is provided, but more than two connecting lines 10 may be provided as needed. Furthermore, while the power source conductor layer 4 is a conductor layer mainly for supplying power source potential to the semiconductor apparatus 6, other than the conductor for the power source, a conductor for ground and a wiring layer for signal can also be provided there.

The ground conductor layer 3 has a ground plane 11 covering almost all over the ground conductor layer 3. The semiconductor apparatus 6 has a ground terminal connected to the ground plane 11 through a via 14. The ground plane 11 has an opening 12 at a position overlapping with an image of the connecting line 10 when projected on the ground conductor layer 3. In the present exemplary embodiment, the opening 12 has a shape approximately the same as that of the image of the connecting line 10 when projected.

The second signal wiring layer 5 is provided with wiring patterns and electronic parts (not illustrated). In the present exemplary embodiment, the ground conductor layer 3 is disposed closer to the first signal wiring layer 2 having the semiconductor apparatus 6 thereon than the power source conductor layer 4, but the power source conductor layer 4 may be disposed closer to the first wiring layer 2.

When the semiconductor apparatus 6 starts to operate, noise current caused by the operation will flow from the IC power supply plane 8 to the main power supply plane 7 through the connecting line 10. At this point, feedback current of the noise will start to flow over the ground plane 11 on the ground conductor layer 3. In other words, the current flowing through the connecting line 10 has reverse phase components to those of the current flowing over the ground plane 11.

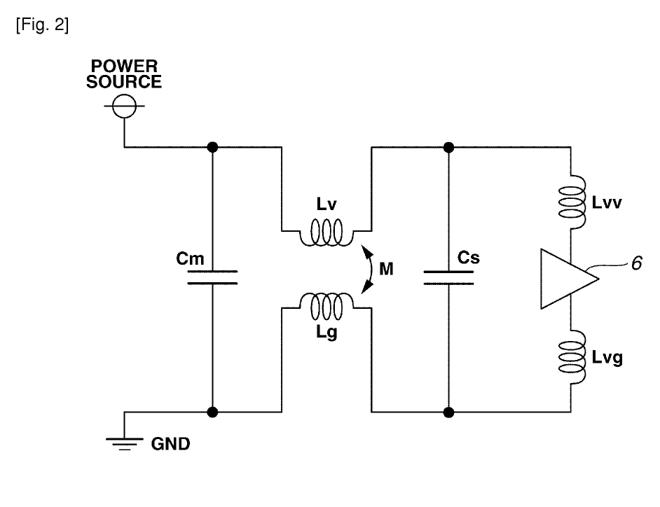

FIG. 2 illustrates an equivalent circuit of the power source conductor layer 4 and the ground conductor layer 3 which constitute an embedded capacitor substrate. In FIG. 2, the circuit has a self inductance component Lv in the connecting line 10, a self inductance component Lg near the opening 12 in the ground plane 11, and a mutual inductance component M between the connecting line 10 and the opening 12 in the ground plane 11, a capacitance component Cm between the main power supply plane 7 and the ground conductor layer 3, and a capacitance component Cs between the IC power supply plane 8 and the ground conductor layer 3.

The circuit further has an inductance component Lvv mainly caused by the via 13 connecting the IC power supply plane 8 to the power source terminal of the semiconductor apparatus 6, and an inductance component Lvg mainly caused by the via 14 connecting the ground conductor layer 3 to the ground terminal of the semiconductor apparatus 6. To suppress propagation of a noise current, an effective inductance Lx of the connecting line 10 is increased. The effective inductance Lx can be expressed as follows.

Lx=Lv+Lg−2M (1)

In this case, directions of the high-frequency current for supplying power to the semiconductor device 6 through the connecting line 10 and that through the ground plane 11 are opposite. Thereby, the mutual inductance component is subtracted from the sum of the inductance components Lv and Lg.

More specifically, if the opening 12 is arranged at a position of an image of the connecting line 10 when projected on the ground conductor layer 3, the mutual inductance component M is extremely reduced, as compared with the case without the opening 12. Accordingly, despite of the size of the opening 12, the opening 12 at a position overlapping with the projected image area reduces the mutual inductance component M, increasing the effective inductance Lx, and enhancing the connect impedance.

In other words, the noise that is otherwise propagated to the entire substrate can be confined within the IC power supply plane 8 by the high impedance connection. As a result, not only the noise radiated from the substrate acting as an antenna, but also the noise propagated to cables through connectors disposed at the ends of the substrate and radiated by the cables and a housing that can act as antennas can be suppressed. In this way, since the impedance at the connecting line 10 becomes high, the noise caused by the operation of the semiconductor device 6 at the IC power supply plane 8 can be suppressed and cannot be propagated to the main power supply plane 7, thus reducing radiation noise.

The opening 12 preferably has a size equal to or more than the projected image when the connecting line 10 is projected onto the ground conductor layer 3. A value of the mutual inductance component M varies inversely proportional to the distance between conductors. Accordingly, in the multi-layer printed circuit board having a thin space between layers, the mutual inductance component M sharply decreases when the conductors are separated from each other out of their opposed positions on the projection plane as seen in the vertical direction. Especially in the embedded capacitor substrate, the decrease is prominent. Thus, a larger opening 12 results in a smaller mutual inductance component M.

Accordingly, the opening 12 having a size equal to or larger than the connecting line 10 can more effectively increase the effective inductance Lx, more effectively suppress the propagation of a noise current, and more effectively reduce radiation noise.

Especially, the opening 12 preferably has a shape approximately the same as that of an image of the connecting line 10 when projected on the ground conductor layer 3. This structure effectively increases the effective inductance Lx while keeping an area of the opening 12 small, so that a sufficient area of the ground plane 11 can be maintained to ensure a returning path of a signal current. Accordingly, the propagation of a noise current can be more effectively suppressed, and radiation noise can be more effectively reduced.

The present invention has been described by way of the above exemplary embodiment, but the present invention is not limited to the exemplary embodiment. The above exemplary embodiment has been described using a multi-layer printed circuit board having four layers, but the same effect can be obtained by a multi-layer printed circuit board having a different number of layers, provided that the printed circuit board is configured to include an embedded capacitor to have the above described structure.

In the above exemplary embodiment, the ground plane 11 is provided with the opening 12 having the same size (rectangular shape) of the connecting line 10, but the opening 12 may be of a different shape.

For example, the ground plane 11 may be divided into a first ground plane containing an image area of the semiconductor apparatus 6 when projected onto the ground conductor layer 3, and a second ground plane provided in the ground conductor layer 3 and separated from the first ground plane by a gap. In this case, an opening needs to be provided so that the ground plane 11 is divided into the first ground plane and the second ground plane. The first ground plane can be connected to the second ground plane by a connecting line, which only needs to be located at a position that does not overlap with an image of the connecting line 10 when projected onto the ground conductor layer 3.

When the IC needs a plurality of different power sources, the first power source plane at an IC power supply unit and the second power source plane at a main power supply unit are configured with a plurality of lines.

### EXAMPLES

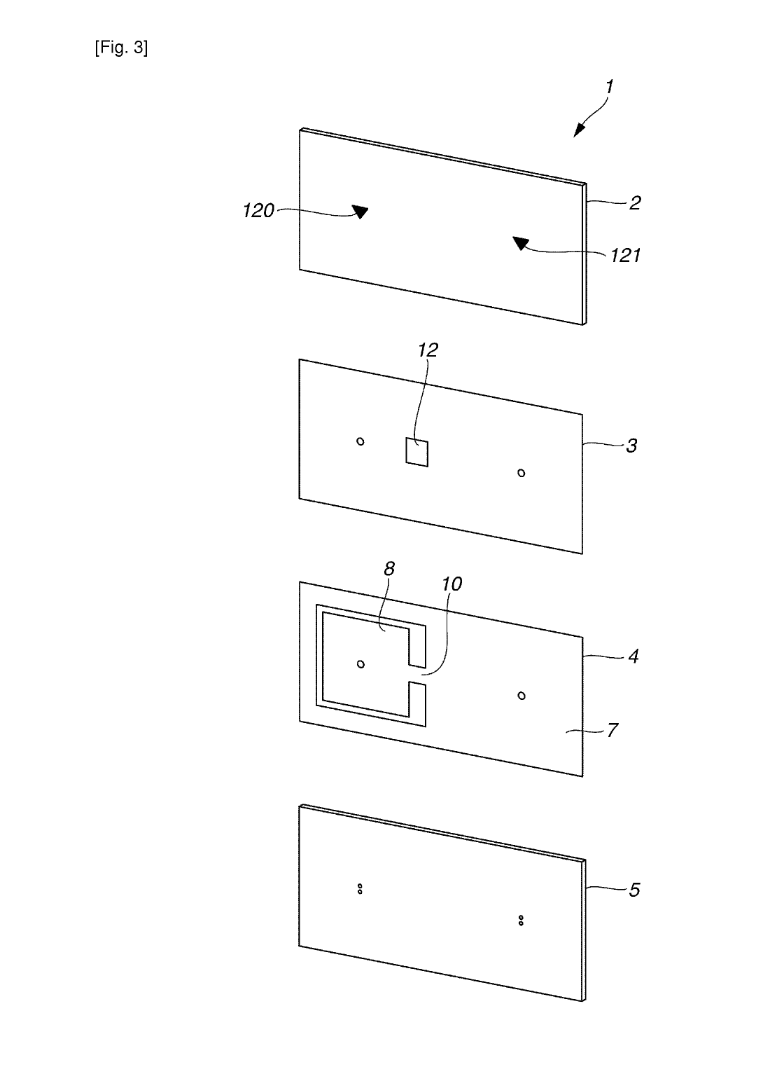

To verify the effect described in the above exemplary embodiment, a simulation was performed using an electromagnetic field simulation software, MW-Studio (manufactured by Computer Simulation Technology Inc. (CST)). FIG. 3 is an exploded perspective diagram illustrating wiring structures of conductor layers of a simulation model in the present Example. FIG. 3 illustrates the first signal wiring layer 2, the ground conductor layer 3, the power source conductor layer 4, and the second signal wiring layer 5. The printed circuit board 1 illustrated in FIG. 3 has a rectangular shape of 40 mm×90 mm. Each of the first signal wiring layer 2, the ground conductor layer 3, the power source conductor layer 4, and the second signal wiring layer 5 is made of a 50 micrometer thick copper.

Between the conductor layers, the insulator layers 21, 22, and 23 (see FIG. 1) each having a relative permittivity of 4.3 are interposed. The insulator layer 21 has a thickness of 100 micrometer, the insulator layer 22 has a thickness of 50 micrometer, and the insulator layer 23 has a thickness of 1.3 mm.

The IC power supply plane 8 is a square of 26 mm×26 mm, and is separated from the main power supply plane 7 by a 4-mm width gap. The IC power supply plane 8 is connected to the main power supply plane 7 by the connecting line 10, which is a strip conductor having a 4-mm length in the direction parallel to the longitudinal direction of the printed circuit board 1, and a 5-mm length in the direction parallel to the lateral direction of the printed circuit board 1. In other words, the connecting line 10 is 4 mm long in its extending direction, and 5 mm long in the direction orthogonal to the extending direction.

The ground plane 11 is provided with the opening 12 of a size to fit (the same size as that of) an image of the connecting line 10 when projected onto the ground conductor layer 3, the opening 12 being 4 mm long in the direction parallel to the longitudinal direction of the printed circuit board 1, and 5 mm long in the direction parallel to the lateral direction of the printed circuit board 1.

An input port 120 is connected, at one end thereof, to the IC power supply plane 8, and to the ground conductor layer 3 at the other end thereof. An output port 121 is connected to the main power supply plane 7 at one end, and to the ground conductor layer 3 at the other end. Each port has a 50 ohm impedance. Using the above described model, noise propagation to the output port 121 when Gaussian pulses with 1-V amplitude were input to the input port 120 was simulated and calculated.

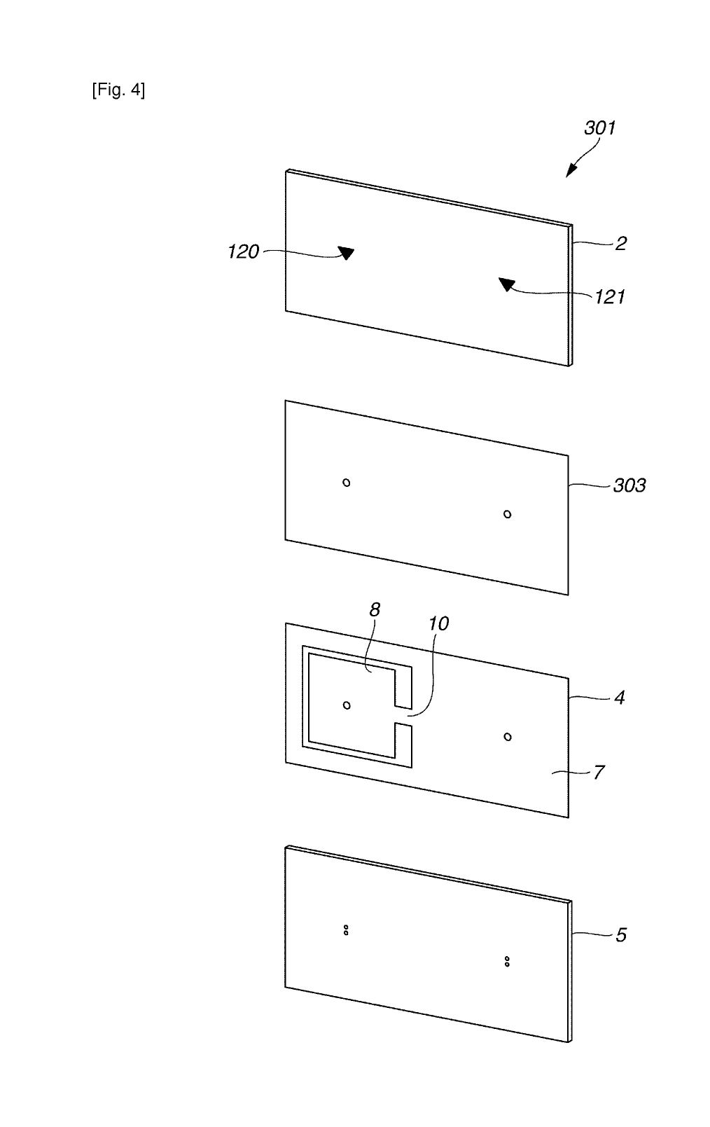

To check the effect of suppressing noise propagation in the present Example, a simulation model for a conventional printed circuit board was made in a Comparative Example, and the resultant calculation in the Comparative Example was compared with that in the Example. FIG. 4 is an exploded perspective diagram illustrating line structures of conductor layers of a simulation model for a printed circuit board 301 in the present Comparative Example. The simulation model for a printed circuit board 301 in the present Comparative Example in FIG. 4 differs from that for the printed circuit board 1 in the Example in FIG. 3 in that the simulation model in the present Comparative Example does not have an opening in a ground conductor layer 302 thereof.

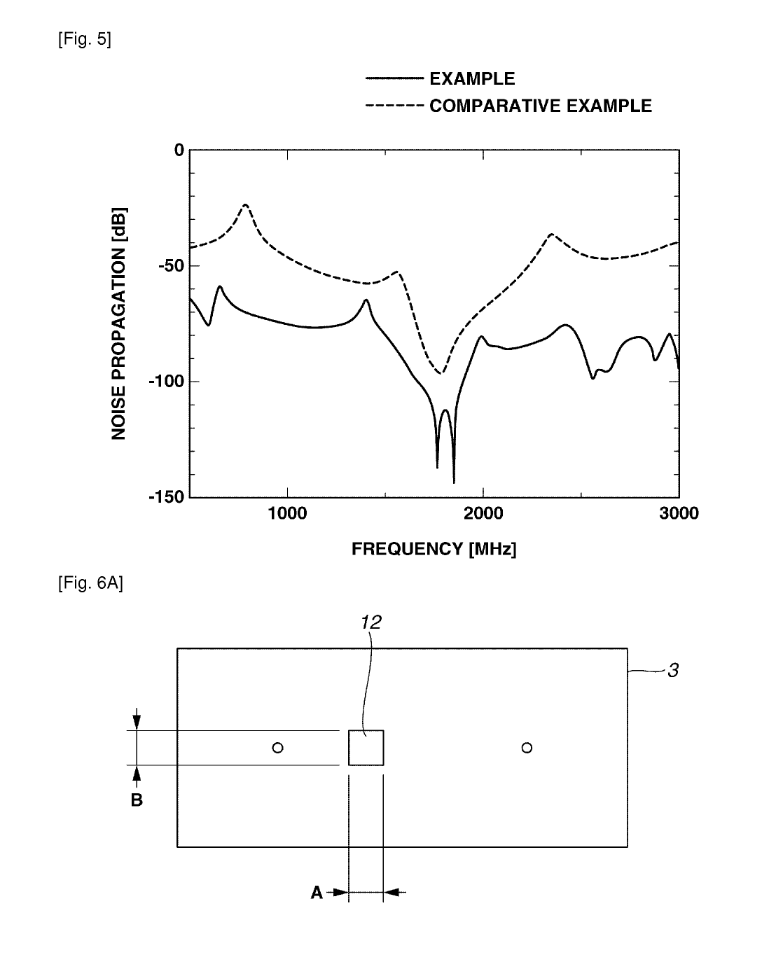

FIG. 5 illustrates simulation results for the printed circuit board 1 in the Example that is depicted by the solid line, and simulation results for the printed circuit board 301 in the present Comparative Example that is depicted by the dashed line. In FIG. 5, the horizontal axis represents frequency, and the vertical axis represents noise propagation. As is obvious from FIG. 5, the propagation of a noise current from the input port 120 to the output port 121 in the printed circuit board 1 in the Example is much less than that in printed circuit board 301 in the Comparative Example. The difference proves that the structure of the printed circuit board 1 in the Example suppresses the propagation of noise current to the entire printed circuit board.

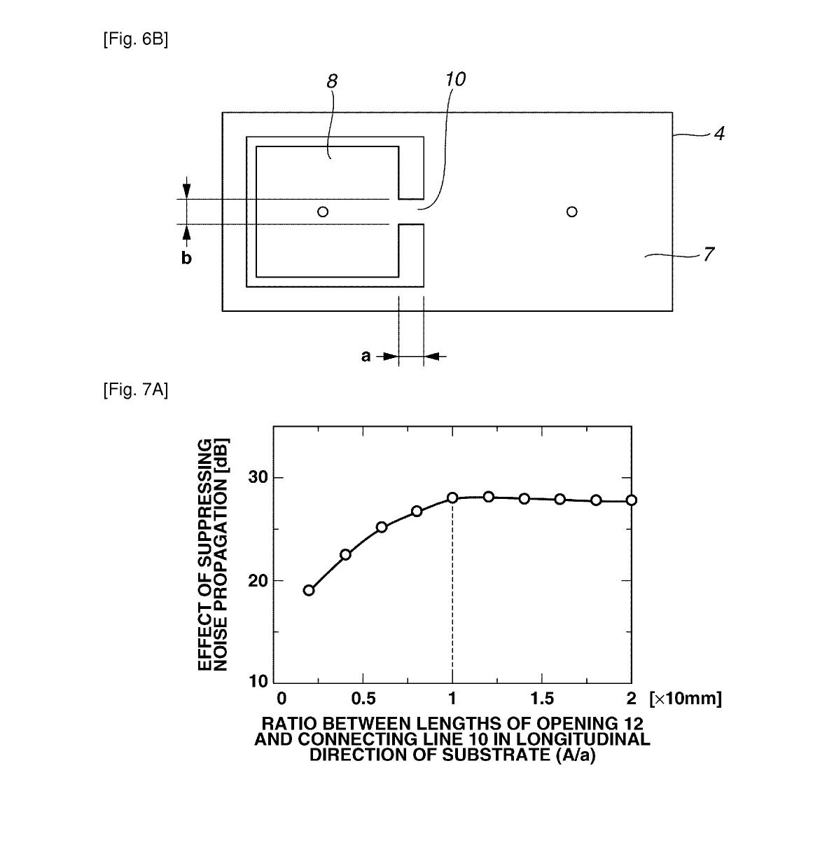

Next, the relationship between the size of the rectangular opening 12 in the ground plane 11 and the effect of suppressing noise propagation was examined: the opening 12 having a side length (the length parallel to the longitudinal direction of the connecting line 10) and another side length (the length parallel to the lateral direction of the connecting line 10). FIGS. 6A and 6B each illustrate a conductor layer as a part of the simulation model for the printed circuit board 1 in the Example as a plan view: FIG. 6A illustrates the ground conductor layer 3; and FIG. 6B illustrates the power source conductor layer 4.

In FIG. 6A, the opening 12 has a side length A parallel to the longitudinal direction of the connecting line 10, and a side length B parallel to the lateral direction of the connecting line 10. In FIG. 6B, the connecting line 10 has a length a in its extending direction, and another length b in its lateral direction.

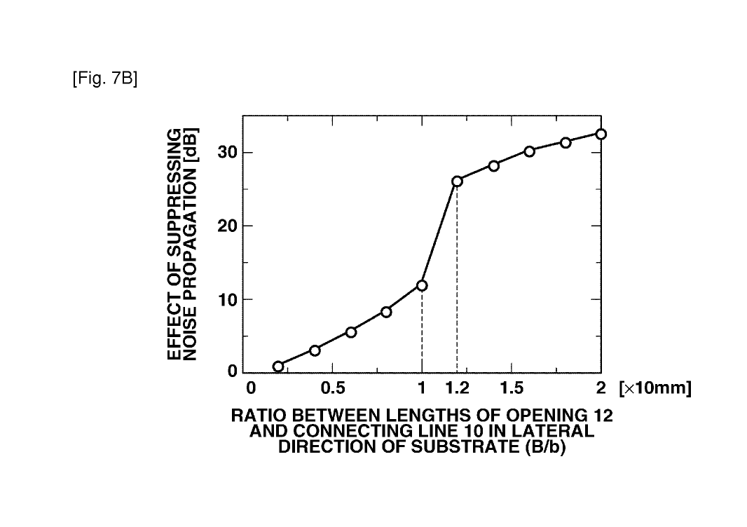

First, the length A of the opening 12 in FIG. 6A was changed in a range from 1 mm to 20 mm to obtain a noise propagation amount by a simulation. The simulated result was compared with a noise propagation amount in the Comparative Example, and the difference is shown in FIG. 7A as the effect of suppressing noise propagation. In FIG. 7A, the horizontal axis represents a ratio (A/a) between the side length A (the length along the longitudinal length of the substrate) of the opening 12 and the length a (the length along the longitudinal length of the substrate) of the connecting line 10, and the vertical axis represents the effect of suppressing noise propagation at frequency of 1.5 GHz.

The effect of suppressing noise propagation shows certain inclination within a wide range from hundreds of MHz to several GHz, and the result in the present Example at the frequency of 1.5 GHz is a typical example.

As illustrated in FIG. 7A, the effect of suppressing noise propagation remains at the almost same level after the ratio (A/a) reaches one. Therefore, the opening 12 having a side length A that is equal to or more than the length a of the connecting line 10 in its extending direction seems to maximize the effect of suppressing noise propagation.

Next, the another length B of the opening 12 in FIG. 6A was changed within a range from 1 mm to 20 mm to obtain a noise propagation amount by simulation. The simulated result was compared with a noise propagation amount in the Comparative Example, and the difference is shown in FIG. 7B as the effect of suppressing noise propagation. In FIG. 7B, the horizontal axis represents a ratio (B/b) between the side length B (the length along the lateral length of the substrate) of the opening 12 and the length b (the length along the lateral length of the substrate) of the connecting line 10, and the vertical axis represents the effect of suppressing noise propagation at frequency of 1.5 GHz.

As illustrated in FIG. 7B, the effect of suppressing noise propagation is increased after the ratio (B/b) reaches one. Especially, the effect is sharply increased between the ratio (B/b) of 1 and the ratio (B/b) of 1.2. Thus, further enhanced effect of suppressing noise propagation is obtained when the ratio (B/b) is equal to or more than 1.2. Therefore, the opening 12 having a side length B that is equal to or more than the length b of the connecting line 10 in its lateral direction maximizes the effect of suppressing noise propagation.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2010-214397 filed Sep. 24, 2010, which is hereby incorporated by reference herein in its entirety.

1. A printed circuit board, wherein
a power source conductor layer;
a ground conductor layer; and
a signal wiring layer having a circuit element thereon;
are multilayered with dielectric layers interposed therebetween, the printed circuit board, comprising;
a first power source plane provided in the power source conductor layer to supply a power source potential to the circuit element, the first power source plane being connected to a power source terminal of the circuit element through a via;
a second power source plane provided in the power source conductor layer separated from the first power source plane by a gap;
a connecting line provided in the power source conductor layer, connecting the first power source plane to the second power source plane; and
a ground plane provided in the ground conductor layer, the ground plane being connected to a ground terminal of the circuit element through a via,
wherein a dielectric layer among the dielectric layers interposed between the power source conductor layer and the ground conductor layer has a thickness equal to or less than 100 micrometer, and
wherein the ground plane has an opening at a portion covering a projected image when the connecting line is projected onto the ground conductor layer.

2. The printed circuit board according to claim 1, wherein the opening has a size equal to or larger than the projected image when the connecting line is projected onto the ground conductor layer.

3. The printed circuit board according to claim 1,
wherein a ratio of the length of the opening to the length of the connecting line is equal to or more than 1 and a ratio of the width of the opening to the width of the connecting line is equal to or more than 1.2.
